(19) United States
(12) Patent Application Publication
(10) Pub. No.: US 2024/0145360 A1
(43) Pub. Date: May 2, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Hwanjoo PARK, Suwon-si (KR); Jaechoon KIM, Suwon-si (KR); Sunggu KANG, Suwon-si (KR); Eunho CHO, Suwon-si (KR); Taehwan KIM, Suwon-si (KR); Jonggyu LEE, Suwon-si (KR)

(21) Appl. No.: 18/244,997

(22) Filed: Sep. 12, 2023

(30) Foreign Application Priority Data
Nov. 1, 2022 (KR) 10-2022-0143307

(51) Int. Cl. H01L 23/498; H01L 23/00; H01L 25/10

(52) U.S. Cl. CPC H01L 23/49811; H01L 23/49838; H01L 24/16; H01L 24/32; H01L 24/73; H01L 25/105; H01L 2224/16225; H01L 2224/32225; H01L 2224/73204; H01L 2224/73253; H01L 2225/1023; H01L 2225/1041; H01L 2924/1434

(57) ABSTRACT

A semiconductor package includes a first redistribution wiring layer having first redistribution wirings, a first semiconductor chip on the first redistribution wiring layer and having a first thickness from the first redistribution wiring layer, a second semiconductor chip disposed on the first redistribution wiring layer spaced apart from the first semiconductor chip and having a second thickness from the first redistribution wiring layer smaller than the first thickness, a sealing member covering the first semiconductor chip and the second semiconductor chip on the first redistribution wiring layer, a plurality of conductive vias provided in the sealing member and electrically connected to the first redistribution wirings, a second redistribution wiring layer disposed on the sealing member and having second redistribution wirings electrically connected to the conductive vias, and at least one third semiconductor chip disposed on the second redistribution wiring layer and electrically connected to the second redistribution wirings.

### CROSS-REFERENCE TO RELATED APPLICATION

This application claims priority under 35 U.S.C. § 119 to Korean Patent Application No. 10-2022-0143307, filed on Nov. 1, 2022 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a multi-chip package including a plurality of different chips in one a package and a method of manufacturing the same.

### 2. Description of the Related Art

In a related 3D IC package-on-package (PoP) package, a lower package may include a lower die provided in a mold and including through-silicon vias (TSVs) formed therein and an upper die stacked on the lower die. A signal from the upper die may be transmitted to a lower redistribution wiring layer through the TSV in the lower die. However, there is a limit to increasing a thickness of the lower die due to limitations in the manufacturing process of the TSV, and due to the relatively limited thickness of the lower die, heat dissipation characteristics may be lowered compared to the upper die and there may be restrictions on IP arrangement.

### SUMMARY

According to example embodiments, a semiconductor package includes a first redistribution wiring layer having first redistribution wirings, a first semiconductor chip disposed on the first redistribution wiring layer, arranged such that a front surface on which first chip pads are formed faces the first redistribution wiring layer and having a first thickness from the first redistribution wiring layer, a second semiconductor chip disposed on the first redistribution wiring layer to be spaced apart from the first semiconductor chip, arranged such that a front surface on which second chip pads are formed faces the first redistribution wiring layer and having a second thickness from the first redistribution wiring layer and smaller than the first thickness, a sealing member covering the first semiconductor chip and the second semiconductor chip on the first redistribution wiring layer, a plurality of conductive vias provided in the sealing member and electrically connected to the first redistribution wirings, a second redistribution wiring layer disposed on the sealing member and having second redistribution wirings electrically connected to the plurality of conductive vias, and at least one third semiconductor chip disposed on the second redistribution wiring layer and electrically connected to the second redistribution wirings.

According to example embodiments, a semiconductor package includes a first redistribution wiring layer including a first chip mounting region, a second chip mounting region and a connector region spaced apart from each other, the first redistribution wiring layer having first redistribution wirings, a first semiconductor chip mounted on the first chip mounting region on the first redistribution wiring layer, a second semiconductor chip mounted on the second chip mounting region on the first redistribution wiring layer, at least one interposer connector disposed on the connector region on the first redistribution wiring layer, the at least one interposer connector including a connector substrate having a plurality of conductive vias penetrating therethrough, first and second connector pads respectively provided at both end portions of the plurality of conductive vias, and conductive bumps respectively formed on the first connector pads, the at least one interposer connector being mounted on the first redistribution wiring layer via the conductive bumps, a sealing member on the first redistribution wiring layer and covering the first semiconductor chip, the second semiconductor chip and the at least one interposer connector, a second redistribution wiring layer disposed on the sealing member and having second redistribution wirings electrically connected to the second connector pads, and a third semiconductor chip disposed on the second redistribution wiring layer, the third semiconductor chip being spaced apart from one side surface of the first semiconductor chip, and electrically connected to the second redistribution wirings. The first semiconductor chip has a first thickness, and the second semiconductor chip has a second thickness less than first thickness.

According to example embodiments, a semiconductor package includes a first redistribution wiring layer including a first chip mounting region, a second chip mounting region and a connector region the first chip mounting region, second chip mounting region and connector region being spaced apart from each other, the first distribution wiring layer having first redistribution wirings, a first semiconductor chip mounted on the first chip mounting region on the first redistribution wiring layer, a second semiconductor chip mounted on the second chip mounting region on the first redistribution wiring layer, a sealing member on the first redistribution wiring layer and covering the first semiconductor chip and the second semiconductor chip, a plurality of conductive vias disposed on the connector region on the first redistribution wiring layer, penetrating the sealing member and electrically connected to the first redistribution wirings, a second redistribution wiring layer disposed on the sealing member and having second redistribution wirings electrically connected to the plurality of conductive vias, and a third semiconductor chip disposed on the second redistribution wiring layer, being spaced apart from one side of the first semiconductor chip and electrically connected to the second redistribution wirings. The first semiconductor chip has a first thickness, and the second semiconductor chip has a second thickness smaller than the first thickness.

According to example embodiments, in a method of manufacturing a semiconductor package, a first semiconductor chip is mounted on a first chip mounting region on a first redistribution wiring layer. A second semiconductor chip is mounted on a second chip mounting region on a first redistribution wiring layer. At least one interposer connector including a connector substrate having a plurality of conductive vias penetrating therethrough, first and second connector pads respectively provided at both end portions of the plurality of conductive vias, and conductive bumps respectively formed on the first connector pads is formed. The at least one interposer connector is mounted on a connector region on the first redistribution wiring layer via the conductive bumps. A sealing member is formed on the first redistribution wiring layer to cover the first semiconductor chip, the second semiconductor chip and the at least one interposer connector. A second redistribution wiring layer is formed on the sealing member, the second redistribution wiring layer having second redistribution wirings electrically connected to the second connector pads.

According to example embodiments, a semiconductor package may include a first redistribution wiring layer having first redistribution wirings, a first semiconductor chip mounted on a first chip mounting region on the first redistribution wiring layer, a second semiconductor chip mounted on a second chip mounting region on the first redistribution wiring layer, a plurality of conductive vias arranged on connector region on the first redistribution wiring layer, a sealing member covering the first semiconductor chip, the second semiconductor chip and the plurality of conductive vias, and a second redistribution wiring layer disposed on the sealing member and having the second redistribution wirings.

The first semiconductor chip and the second semiconductor chip may be spaced apart from each other on the first redistribution wiring layer, and the first semiconductor chip and the second semiconductor chip may have relatively large thicknesses without thickness restrictions. Further, an upper portion of the first semiconductor chip may be exposed by the sealing member.

Thus, heat dissipation characteristics of the first and second semiconductor chips may be improved due to high thermal conductivity of silicon. Since the first and second semiconductor chips are horizontally spaced apart from each other, thermal coupling between them may be reduced.

### BRIEF DESCRIPTION OF THE DRAWINGS

Features will become apparent to those of skill in the art by describing in detail exemplary embodiments with reference to the attached drawings in which:

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view of FIG. 1.

FIGS. 4 to 9 are views illustrating a method of manufacturing a semiconductor package in accordance with example embodiments.

FIG. 10 is a cross-sectional view illustrating a semiconductor package in accordance with example embodiments.

FIGS. 11 to 15 are cross-sectional views illustrating a method of manufacturing a semiconductor package in accordance with example embodiments.

FIG. 16 is a cross-sectional view illustrating a semiconductor package in accordance with example embodiments

### DETAILED DESCRIPTION

Hereinafter, example embodiments will be explained in detail with reference to the accompanying drawings.

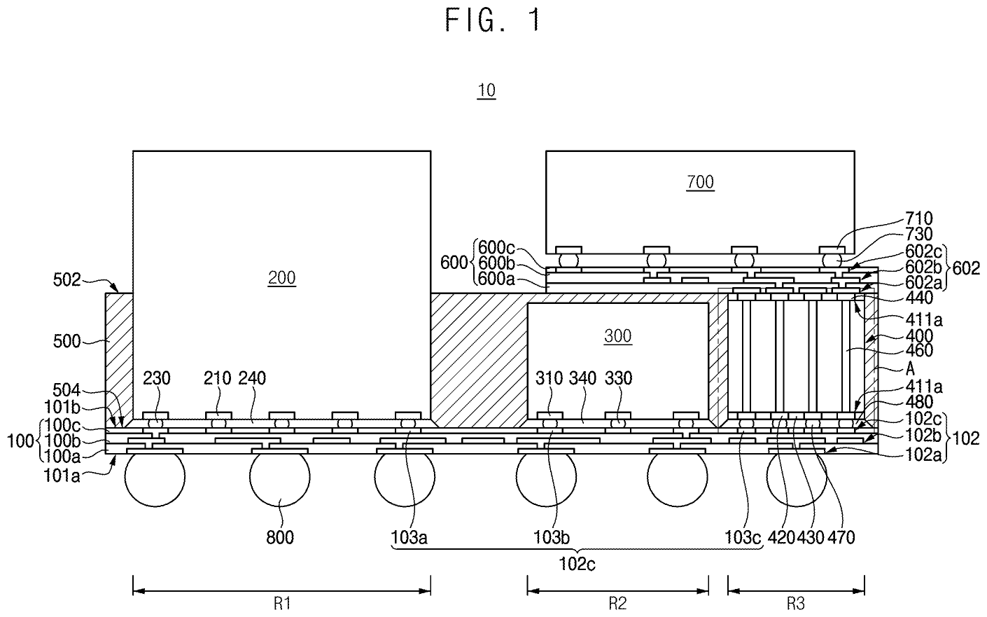

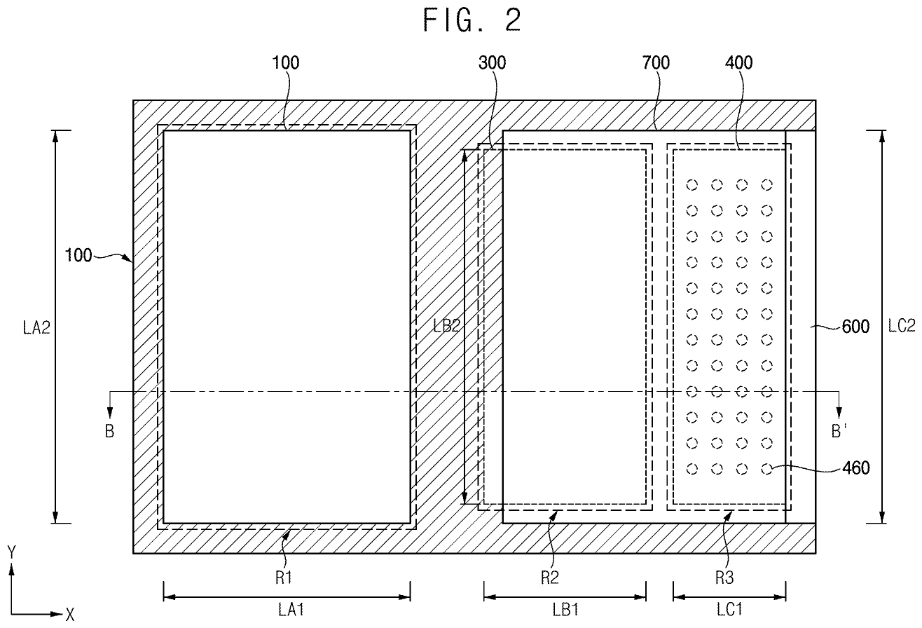

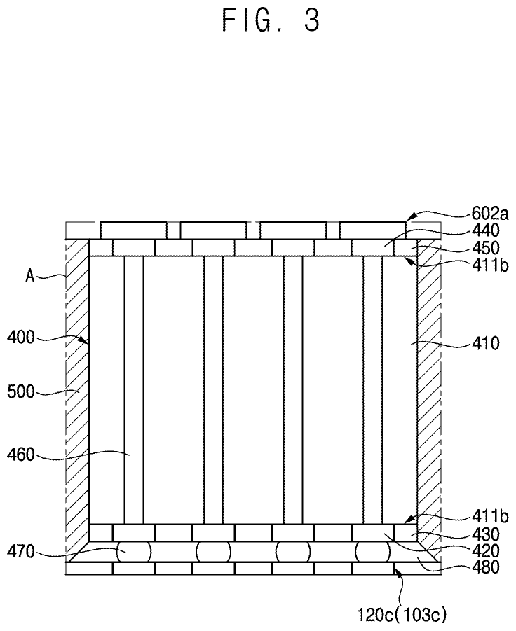

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view of FIG. 1. FIG. 1 is a cross-sectional view taken along the line B-B′ in FIG. 3.

As shown in FIGS. 1 to 3, a semiconductor package 10 may include a first redistribution wiring layer 100, a first semiconductor chip 200, a second semiconductor chip 300, at least one interposer connector 400, a sealing member 500 and a second redistribution wiring layer 600 The semiconductor package 10 may further include a third semiconductor chip 700 and external connection members 800.

The semiconductor package 10 may be used as a package on package (FO Package On Package). The semiconductor package 10 may be a multi-chip package (MCP) including different types of semiconductor chips. The semiconductor package 10 may be a system in package (SIP) having a plurality of semiconductor chips stacked or arranged in one package to perform all or most of the functions of an electronic system.

In example embodiments, the first redistribution wiring layer 100, which may be a front redistribution wiring layer, may include first redistribution wirings 102. The first redistribution wiring layer 100 may include first to third lower insulating layers 100a, 100b, and 100c stacked on one another and on the first redistribution wirings 102 in the stacked first to third lower insulating layers 100a, 100b and 100c. The first redistribution wirings 102 may include first to third lower redistribution wirings 102a, 102b and 102c. A thickness of the first redistribution wiring layer 100 may be, for example, in a range of 5 μm to 50 μm.

The first redistribution wiring layer 100 may have a first surface 101a and a second surface 101b opposite to the first surface 101a. As viewed from a plan view, the first redistribution wiring layer 100 may include a first region R1, a second region R2 and a third region R3 spaced apart from each other. The first region R1, the second region R2 and the third region R3 may be spaced apart from each other along a first direction (X direction). The first region R1 may be a first chip mounting region in which the first semiconductor chip 200 is mounted on the second surface 101b of the first redistribution wiring layer 100. The second region R2 may be a second chip mounting region in which the second semiconductor chip 300 is mounted on one side of the first semiconductor chip 200 on the second surface 101b of the first redistribution wiring layer 100. The third region R3 may be a connector area in which the at least one interposer connector 400 is mounted in one side of the second semiconductor chip 300 on the second surface 101b of the first redistribution wiring layer 100.

The uppermost redistribution wirings 102c, that is, the third lower redistribution wirings of the first redistribution wirings 102, may include first uppermost redistribution wirings 103a disposed in the first region R1 and electrically connected to first chip pads 210 of the first semiconductor chip 200, second uppermost redistribution wirings 103b disposed in the second region R2 and electrically connected to second chip pads 310 of the second semiconductor chip 300, and third uppermost redistribution wirings 103b disposed in the third region R3 and electrically connected to first connector pads 420 of the interposer connector 400. Bump pads such as may be formed using under bump metallurgy (UBM), may be formed on redistribution pad portions of the first to third uppermost redistribution wirings 103a, 103b and 103c, respectively.

Additionally, the first to third uppermost redistribution wirings 103a, 103b and 103c may be electrically connected to each other. Accordingly, the first semiconductor chip 200, the second semiconductor chip 300 and the interposer connector 400 may be electrically connected to each other.

A first lower insulating layer 100a may expose at least portions of the first lower redistribution wirings 102a. The first lower insulating layer 100a may serve as a passivation layer. A bump pad (not illustrated), such as may be formed by UBM, may be provided on the first lower redistribution wiring 102a exposed by the first lower insulating layer 100a. In this case, the exposed portion of the first lower redistribution wiring 102a may serve as a landing pad, that is, a package pad.

The numbers, sizes, arrangements, etc. of the lower insulating layers and the lower redistribution wirings of the first redistribution wiring layer are provided as non-limiting examples, and it is to be understood that the embodiments are not limited thereto.

In example embodiments, the first semiconductor chip 200 may be arranged in the first region R1 of the first redistribution wiring layer 100. The first semiconductor chip 200 may be mounted on the second surface 101b of the first redistribution wiring layer 100 by a flip chip bonding method. The first semiconductor chip 200 may be arranged such that a front surface on which the first chip pads 210 are formed, that is, an active surface, faces the first redistribution wiring layer 100. The first chip pads 210 of the first semiconductor chip 200 may be electrically connected to the first redistribution wirings 102 of the first redistribution wiring layer 100, that is, to the first uppermost redistribution wirings 103a, by first conductive bumps 230.

Similar to an arrangement of the first semiconductor chip, the second semiconductor chip 300 may be arranged in the second region R2 of the first redistribution wiring layer 100. The second semiconductor chip 300 may be mounted on the second surface 101b of the first redistribution wiring layer 100 by a flip chip bonding method. The second semiconductor chip 300 may be arranged such that a front surface on which the second chip pads 310 are formed, that is, an active surface, faces the first redistribution wiring layer 100. The second chip pads 310 of the second semiconductor chip 300 may be electrically connected to the first redistribution wirings 102 of the first redistribution wiring layer 100, that is, to the second uppermost redistribution wirings 103b, by second conductive bumps 330.

The first semiconductor chip and the second semiconductor chip may be logic chips that include logic circuits. Each logic chip may be a controller that controls memory chips. The first and second semiconductor chips may be ASICs serving as hosts such as CPUs, NPUs, GPUs, and SOCs, or processor chips such as application processors (APs).

The first and second conductive bumps 220 and 330 may include, for example, micro bumps (uBumps). The first and second conductive bumps may include a pillar portion formed on the first or second chip pad and a solder portion formed on the pillar portion. The pillar portion may include copper (Cu), nickel (Ni), palladium (Pd), platinum (Pt), gold (Au), cobalt (Co), or an alloy thereof. The solder portion may include tin (Sn), indium (In), antimony (Sb), copper (Cu), silver (Ag), zinc (Zn), lead (Pb), or an alloy thereof.

The first and second underfill members 240 and 340 may be underfilled between the first semiconductor chip 200 and the first redistribution wiring layer 100 and between the second semiconductor chip 300 and the first redistribution wiring layer 100. The first and second underfill members may include a material having relatively high fluidity to effectively fill small spaces between the first semiconductor chip and the first redistribution wiring layer and between the second semiconductor chip and the first redistribution wiring layer. For example, the first and second underfill members may include an adhesive containing an epoxy material.

In example embodiments, the at least one interposer connector 400 may be arranged in the third region R3 of the first redistribution wiring layer 100. The interposer connector 400 may be mounted on the second surface 101b of the first redistribution wiring layer 100 by a flip chip bonding method. The interposer connector 400 may be arranged such that a first surface 411a on which the first connector pads 420 are formed faces the first redistribution wiring layer 100. The first connector pads 420 of the interposer connector 400 may be electrically connected to the first redistribution wirings 102 of the first redistribution wiring layer 100, that is, the third uppermost redistribution wirings 103c by conductive bumps 470.

As illustrated in FIG. 3, the interposer connector 400 may include a connector substrate 410 in which a plurality of conductive vias 460 are formed to extend through, first and second connector pads 420 and 440 provided on both ends of each of the plurality of conductive vias 460, and the conductive bumps 470 respectively formed on the first connector pads 420.

For example, the first semiconductor chip 200 may have a first height from the second surface 101b of the first redistribution wiring layer 100, and the second semiconductor chip 300 may have a second height smaller than the first height from the second surface 101b of the first redistribution wiring layer 100. The interposer connector 400 may have a third height greater than or equal to the second height from the second surface 101b of the first redistribution wiring layer 100. For example, a thickness of the first semiconductor chip 200 may be in a range of 0.5 mm to 1.0 mm, and a thickness of the second semiconductor chip 300 may be in a range of 0.1 mm to 0.5 mm. A diameter of the conductive bump 470 may be in a range of 30 μm to 300 μm.

As illustrated in FIG. 2, the first redistribution wiring layer 100 may have a quadrangular shape having four side surfaces. The first redistribution wiring layer 100 may have an area of 10 mm×7 mm or more. The first semiconductor chip 200 may have an area of 7 mm×7 mm or more. The second semiconductor chip 300 may have an area of 5 mm×7 mm or more. A length of one side LA1, LA2 of the first semiconductor chip 200 may be in a range of 7 mm to 15 mm. A length of one side LB1, LB2 of the second semiconductor chip 300 may be in a range of 5 mm to 15 mm.

The interposer connector 400 may have a rectangular shape extending in one direction. The interposer connector 400 extending along one side of the second semiconductor chip 300 may have a short side LC1 in a first direction (X direction) and a long side LC2 in a second direction (Y direction). A length of the long side LC2 of the interposer connector 400 may be equal to the length of one side of the second semiconductor chip 300. The length of the short side LC1 of the interposer connector 400 may be in a range of 1 mm to 3 mm, and the length of the long side LC2 of the interposer connector 400 may be in a range of 7 mm to 15 mm.

The lengths of the short side and the long side of the interposer connector, the height of the interposer connector, the arrangement of the conductive vias, etc. are provided as examples. It is to be understood that embodiments are not limited thereto. The lengths of the short and long sides of the interposer connector, the height of the interposer connector, and the arrangement of the conductive vias may be determined in consideration of the thickness, warpage, and heat dissipation characteristics of the entire package.

In example embodiments, the sealing member 500 may cover the first semiconductor chip 200, the second semiconductor chip 300 and the interposer connector 400 on the second surface 101b of the first redistribution wiring layer 100. An upper portion of the first semiconductor chip 200 and the second connector pads 440 of the interposer connector 400 may be exposed by an upper surface 502 of the sealing member 500. An upper surface of the second semiconductor chip 300 may be covered by the sealing member 500.

For example, the sealing member 500 may include an epoxy molding compound (EMC). The sealing member 500 may include UV resin, polyurethane resin, silicone resin, silica filler, etc.

In example embodiments, the second redistribution wiring layer 600 as a backside redistribution wiring layer may be disposed on the sealing member 500. The second redistribution wiring layer 600 may include second redistribution wirings 212. The second redistribution wirings 602 may be electrically connected to the second connector pads 440. The second redistribution wiring layer 600 may be disposed on the second semiconductor chip 300 and the interposer connector 400. The second redistribution wiring layer 600 may be arranged to at least partially overlap the second semiconductor chip 300.

The second redistribution wiring layer 600 may include first to third upper insulating layers 600a, 600b and 600c stacked on one another and the second redistribution wirings 602 in the stacked first to third upper insulating layers 600a, 600b and 600c. The second redistribution wirings 602 may include first to third upper redistribution wirings 602a, 602b, and 602c. The second redistribution wiring layer 600 may have a first surface 601a and a second surface 601b opposite to the first surface 601a.

The third upper insulating layer 600c may have openings that expose the third upper redistribution wirings 602c respectively. The third upper redistribution wirings 602c exposed by the openings may be outermost redistribution wirings. A portion of the outermost redistribution may include a redistribution pad portion. Although not illustrated in the figures, a bump pad such as a UBM may be formed on the redistribution pad portion.

The numbers, sizes, arrangements, etc. of the upper insulating layers and the upper redistribution wirings of the second redistribution wiring layer are provided as examples, and it will be understood that the embodiments are not limited thereto.

In example embodiments, the semiconductor package 10 may include a lower package and an upper package stacked on the lower package. The lower package may include the first redistribution wiring layer 100, the first semiconductor chip 200, the second semiconductor chip 300, the at least one interposer connector 400, the sealing member 500 and the second redistribution wiring layer 600. The upper package may be disposed on the second redistribution wiring layer 600 of the lower package.

The third semiconductor chip 700 as the upper package may be stacked on the second redistribution wiring layer 600. The third semiconductor chip 700 may be mounted on the second surface 201b of the second redistribution wiring layer 600 by a flip chip bonding method. The third semiconductor chip 700 may be arranged such that a front surface on which third chip pads 710 are formed, that is, an active surface faces the second redistribution wiring layer 600. The third chip pads 710 of the third semiconductor chip 700 may be electrically connected to the second redistribution wirings 602 of the second redistribution wiring layer 600 by third conductive bumps 730.

Although one third semiconductor chip is illustrated as being mounted on the second redistribution wiring layer 600, in some implementations, the upper package may include a package substrate and at least one third semiconductor chip mounted on the package substrate. The package substrate of the upper package may be mounted on the second redistribution wiring layer via the third conductive bumps.

In example embodiments, the external connection members 800 for electrical connection with an external device may be disposed on the package pads on the first surface 101a of the first redistribution wiring layer 100. For example, the external connection member 800 may be a solder ball or a solder bump. The semiconductor package 10 may be mounted on a module substrate (not illustrated) or an interposer via the solder balls or the solder bumps.

As mentioned above, the semiconductor package 10 may include the first chip mounting region R1, the second chip mounting region R2 and the connector region R3 spaced apart in a horizontal direction, and may include the first redistribution wiring layer 100 having the first redistribution wirings 102, the first semiconductor chip 200 mounted on the first chip mounting region R1 on the first redistribution wiring layer 100, the second semiconductor chip 300 mounted on the second chip mounting region R2 on the first redistribution wiring layer 100, the at least one interposer connector 400 disposed on the connector region R3 on the first redistribution wiring layer 100 and having the connector substrate 410 with the plurality of conductive vias 460 formed therethrough, the sealing member 500 covering the first semiconductor chip 200, the second semiconductor chip 300 and the plurality of conductive vias 460 on the first redistribution wiring layer 100, and the second redistribution wiring layer 600 disposed on the sealing member 500 and having the second redistribution wirings 602.

The first semiconductor chip 200 and the second semiconductor chip 300 may be spaced apart from each other on the first redistribution wiring layer 100, and the first semiconductor chip 200 and the second semiconductor chip 300 may have relatively large thicknesses without thickness restrictions. Further, the upper portion of the first semiconductor chip 200 may be exposed by the sealing member 500.

Thus, heat dissipation characteristics of the first and second semiconductor chips 200 and 300 may be improved due to the high thermal conductivity of silicon. Since the first and second semiconductor chips 200 and 300 are horizontally spaced apart from each other, thermal coupling between them may be reduced.

Hereinafter, a method of manufacturing the semiconductor package of FIG. 1 will be described.

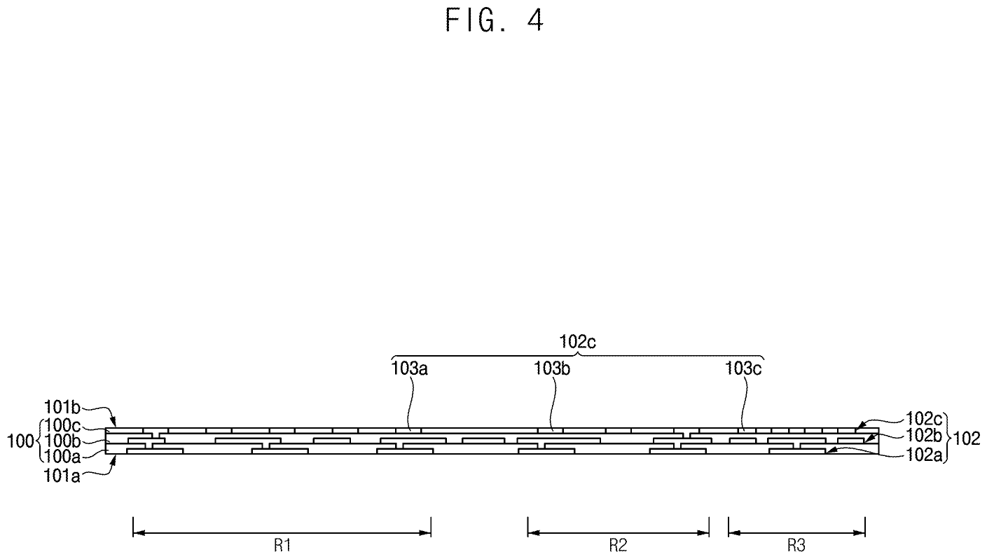

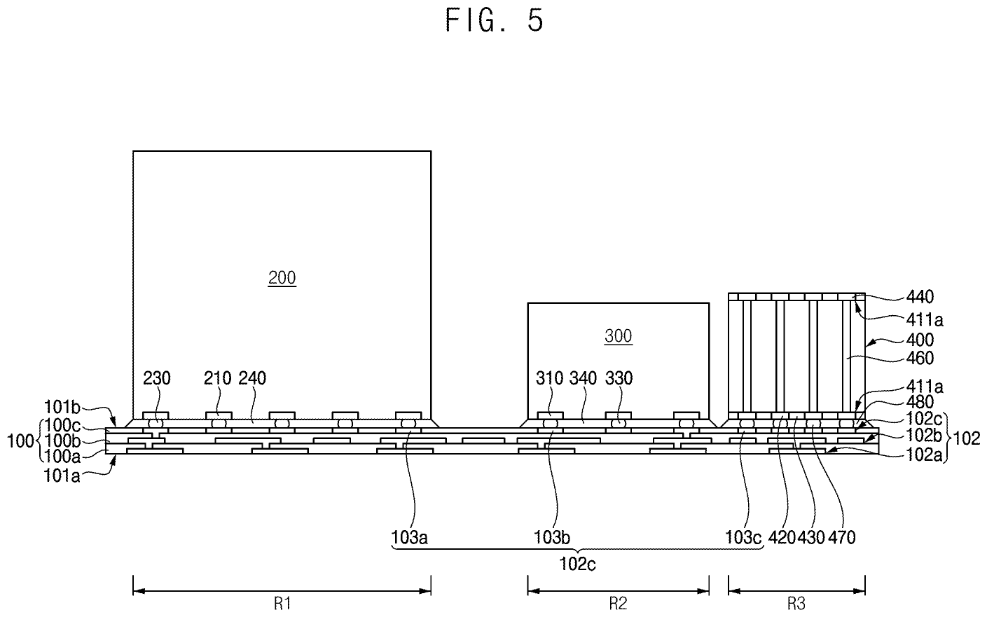

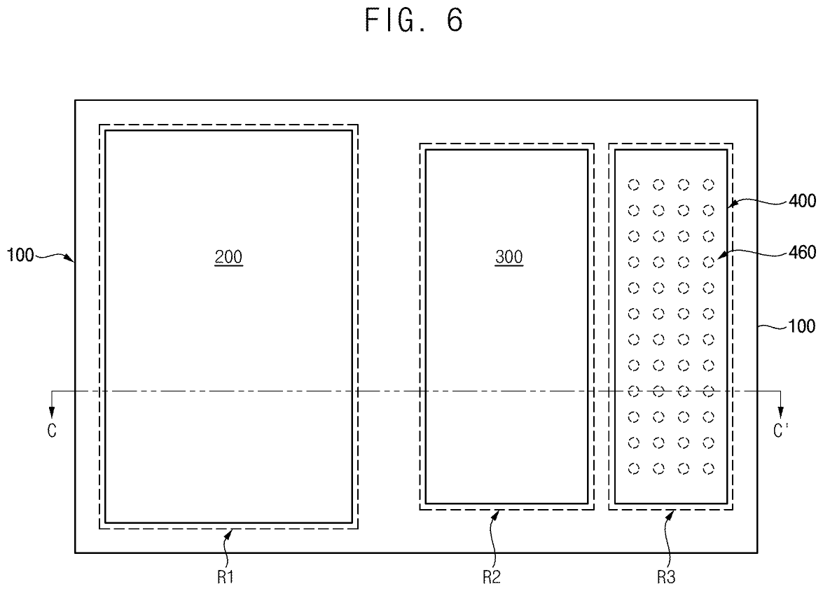

FIGS. 4 to 9 are views illustrating a method of manufacturing a semiconductor package in accordance with example embodiments. FIGS. 4, 5 and 7 to 9 are cross-sectional views illustrating a method of manufacturing a semiconductor package in accordance with example embodiments. FIG. 6 is a plan view of FIG. 5. FIG. 5 is a cross-sectional view taken along the line C-C′ in FIG. 6.

Referring to FIG. 4, a first redistribution wiring layer 100 having first redistribution wirings 102 may be formed on a first carrier substrate Cl.

In some implementations, as will be described later, first lower redistribution wirings 102a may be formed on the first carrier substrate Cl, and a first lower insulating layer 100a may be formed on the first carrier substrate Cl to cover the first lower redistribution wirings 102a.

The first lower redistribution wirings 102a may be formed by, for example, an electroplating process. After a seed layer is formed on the first carrier substrate Cl, the seed layer may be patterned and the electroplating process may be performed to form the first lower redistribution wirings. The first lower redistribution wiring may include aluminum (Al), copper (Cu), tin (Sn), nickel (Ni), gold (Au), platinum (Pt), or an alloy thereof.

Although not illustrated in the figures, after bonding pads for bonding with conductive bumps are formed on the first carrier substrate Cl, the first lower redistribution wirings may be formed on the bonding pads. In some implementations, as will be described later, after forming a first semiconductor chip, a second semiconductor chip and a second redistribution wiring layer on the first redistribution wiring layer 100, bonding pads such as UBM may be formed on redistribution pad portions of the first lower redistribution wirings.

The first lower insulating layer 100a may include a polymer or a dielectric layer. The first lower insulating layer 100a may include polyimide (PI), lead oxide (PbO), polyhydroxystyrene (PHS), novolac, as examples. The first lower insulating layer 100a may be formed by a vapor deposition process, a spin coating process, etc.

Then, after the first lower insulating layer 100a is patterned to form openings that expose the first lower redistribution wirings 102a, second lower redistribution wirings 102b may be formed on the first lower insulating layer 100a to be electrically connected to the first lower redistribution wirings 102a through the openings.

For example, a seed layer may be formed on a portion of the first lower insulating layer 100a and in the opening, the seed layer may be patterned. An electroplating process may be performed to form the second lower redistribution wirings 102b. Accordingly, at least a portion of the second lower redistribution wiring 102b may directly contact the first lower redistribution wiring 102a through the opening.

Similarly, after a second lower insulating layer 100b is formed on the first lower insulating layer 100a to cover the second lower redistribution wirings 102b, the second lower insulating layer 100b may be patterned to form openings that expose the second lower redistribution wirings 102b. Then, third lower redistribution wirings 102c may be formed on the second lower insulating layer 100b to be electrically connected to the second lower redistribution wirings 102b through the openings.

Then, after a third lower insulating layer 100c is formed on the second lower insulating layer 100b to cover the third lower redistribution wirings 102c, the third lower insulating layer 100c may be patterned to form openings that expose the third lower redistribution wirings 102c. The third lower redistribution wirings 102c exposed by the opening may be uppermost redistribution wirings. A portion of the uppermost redistribution wiring may include a redistribution pad portion. Although not illustrated in the figures, a bump pad such as a UBM may be formed on the redistribution pad portion.

Thus, the first redistribution wiring layer 100 having the first redistribution wirings 102 as a front redistribution wiring layer (FRDL) may be formed on the first carrier substrate Cl. The first redistribution wiring layer 100 may include the stacked first to third lower insulating layers 100a, 100b and 100c and the first redistribution wirings 102 in the stacked first to third lower insulating layers 100a, 100b and 100c. The first redistribution wiring 102 may include the first to third lower redistribution wirings 102a, 102b and 102c. For example, a thickness of the first redistribution wiring layer 100 may be within a range of 5 μm to 50 μm.

The first redistribution wiring layer 100 may have a first surface 101a and a second surface 101b opposite to the first surface 101a. The first redistribution wiring layer 100 may include a first region R1, a second region R2 and a third region R3 spaced apart from each other. As will be described later, when viewed from a plan view, the first region R1 may be a first chip mounting region in which a first semiconductor chip is mounted on the second surface 101b of the first redistribution wiring layer 100. The second region R2 may be a second chip mounting region in which a second semiconductor chip is mounted in one side of the first semiconductor chip on the second surface 101b of the first redistribution wiring layer 100. The third region R3 may be a connector region in which at least one interposer connector is mounted in one side of the second semiconductor chip on the second surface 101b of the first redistribution wiring layer 100.

The uppermost redistribution wirings 102c of the first redistribution wiring 102 may include first uppermost redistribution wirings 103a disposed in the first region R1 and electrically connected to first chip pads of the first semiconductor chip, second uppermost redistribution wirings 103b disposed in the second region R2 and electrically connected to second chip pads of the second semiconductor chip, and third uppermost redistribution wirings 103b disposed in the third region R3 and electrically connected to first connector pads of the interposer connector. Bump pads such as UBM may be formed on redistribution pad portions of the first to third uppermost redistribution wirings 103a, 103b and 103c.

Additionally, the first to third uppermost redistribution wirings 103a, 103b and 103c may be electrically connected to each other. Accordingly, the first semiconductor chip, the second semiconductor chip and the interposer connector may be electrically connected to each other.

The numbers, sizes, arrangements, etc. of the lower insulating layers and the lower redistribution wirings of the first redistribution wiring layer are provided as examples, and it will be understood that embodiments are not limited thereto.

Referring to FIGS. 5 and 6, a first semiconductor chip 200, a second semiconductor chip 300 and at least one interposer connector 400 may be arranged on the second surface 101b of the first redistribution wiring layer 100.

In example embodiments, the first semiconductor chip 200 may be disposed in the first region R1 of the first redistribution wiring layer 100. The first semiconductor chip 200 may be mounted on the second surface 101b of the first redistribution wiring layer 100 by a flip chip bonding method. The first semiconductor chip 200 may be arranged such that a front surface on which the first chip pads 210 are formed, that is, an active surface, faces the first redistribution wiring layer 100. The first chip pads 210 of the first semiconductor chip 200 may be electrically connected to the first redistribution wirings 102 of the first redistribution wiring layer 100, that is, the first uppermost redistribution wirings 103a by first conductive bumps 230.

Similar to the forming of the first semiconductor chip, the second semiconductor chip 300 may be disposed in the second region R2 of the first redistribution wiring layer 100. The second semiconductor chip 300 may be mounted on the second surface 101b of the first redistribution wiring layer 100 by a flip chip bonding method. The second semiconductor chip 300 may be arranged such that a front surface on which the second chip pads 310 are formed, that is, an active surface, faces the first redistribution wiring layer 100. The second chip pads 310 of the second semiconductor chip 300 may be electrically connected to the first redistribution wirings 102 of the first redistribution wiring layer 100, that is, the second uppermost redistribution wirings 103b, by second conductive bumps 330.

The first semiconductor chip and the second semiconductor chip may be logic chips including logic circuits. The logic chip may be a controller that controls memory chips. The first and second semiconductor chips may be ASICs serving as hosts such as CPUs, NPUs, GPUs, and SOCs, and processor chips such as application processors (APs).

For example, the first and second conductive bumps 220 and 330 may include micro bumps (uBumps). The first and second conductive bumps may include a pillar portion formed on the first and second chip pad and a solder portion formed on the pillar portion. The pillar portion may include copper (Cu), nickel (Ni), palladium (Pd), platinum (Pt), gold (Au), cobalt (Co), or an alloy thereof. The solder portion may include tin (Sn), indium (In), antimony (Sb), copper (Cu), silver (Ag), zinc (Zn), lead (Pb), or an alloy thereof.

First and second underfill members 240 and 340 may be underfilled between the first semiconductor chip 200 and the first redistribution wiring layer 100 and between the second semiconductor chip 300 and the first redistribution wiring layer 100. The first and second underfill members may include a material having relatively high fluidity to effectively fill small spaces between the first semiconductor chip and the first redistribution wiring layer and between the second semiconductor chip and the first redistribution wiring layer. For example, the first and second underfill members may include an adhesive containing an epoxy material.

In example embodiments, at least one interposer connector 400 may be formed, The at least one interposer connector 400 may be arranged on the second surface 101b of the first redistribution wiring layer 100.

First, conductive vias 460 may be formed in a first surface of a substrate such as a silicon wafer W to partially penetrate the substrate. First connector pads 420 may be formed on the first surface of the substrate to be electrically connected to end portions of the conductive vias 460. Then, conductive bumps 470 may be formed on the first connector pads 420. A diameter of the conductive bump 470 may be, for example, in a range of 30 μm to 300 μm.

Then, a second surface opposite to the first surface of the substrate may be partially removed to expose the other end portions of the conductive vias 460 Second connector pads 440 may be formed on the second surface of the substrate to be electrically connected to the other end portions of the conductive vias 460.

Then, the substrates may be individually separated by a sawing process to form the at least one interposer connector 400. The substrate may be cut such that the interposer connector 400 has a desired shape. The interposer connector 400 may have a rectangular shape having a short side in a first direction and a long side in a second direction perpendicular to the first direction.

The interposer connector 400 may include: a connector substrate 410 through which the plurality of conductive vias 460 are formed, the first and second connector pads 420 and 440 provided at both end portions of each of the plurality of conductive vias 460 respectively, and the conductive bumps 470 respectively formed on the first connector pads 420.

The conductive vias 460 may be spaced apart from each other along one direction within the connector substrate 410. The interposer connector 400 may include a conductive via array arranged in a plurality of columns. For example, the interposer connector 400 may include first to fourth columns of conductive vias arranged in parallel directions.

Then, the at least one interposer connector 400 may be mounted on the third region R3 of the first redistribution wiring layer 100 via the conductive bumps 470.

The interposer connector 400 may be disposed, for example, in the third region R3 of the first redistribution wiring layer 100. The interposer connector 400 may be mounted on the second surface 101b of the first redistribution wiring layer 100 by a flip chip bonding method. The interposer connector 400 may be arranged such that the first connector pads 420 on which the conductive bumps 470 are formed face the first redistribution wiring layer 100. A thermal compression process or a reflow process may be performed to bond the conductive bumps 470 to the first redistribution wirings 102 of the first redistribution wiring layer 100, that is, the bump pads on the third uppermost redistribution wirings 103c. The first connector pads 420 of the interposer connector 400 may be electrically connected to the first redistribution wirings 102 of the first redistribution wiring layer 100 by the conductive bumps 470, that is, the third uppermost redistribution wirings 103c. A third underfill member 480 may be underfilled between the interposer connector 400 and the first redistribution wiring layer 100.

The first semiconductor chip 200 may have a first height, for example, from the second surface 101b of the first redistribution wiring layer 100 The second semiconductor chip 300 may have a second height less than the first height from the second surface 101b of the first redistribution wiring layer 100 The interposer connector 400 may has a third height greater than or equal to the second height from the second surface 101b of the first redistribution wiring layer 100. A thickness of the first semiconductor chip 200 may be, for example, in a range of 0.5 mm to 1.0 mm. A thickness of the second semiconductor chip 300 may be in a range of 0.1 mm to 0.5 mm.

The first redistribution wiring layer 100 may have a quadrangular shape having four side surfaces. The first redistribution wiring layer 100 may have an area of 10 mm×7 mm or more. The first semiconductor chip 200 may have an area of 7 mm×7 mm or more. The second semiconductor chip 300 may have an area of 5 mm×7 mm or more. A length of one side of the first semiconductor chip 200 may be in a range of 7 mm to 15 mm. A length of one side of the second semiconductor chip 300 may be in a range of 5 mm to 15 mm.

The interposer connector 400 may have a rectangular shape extending in one direction. The interposer connector 400 extending along one side of the second semiconductor chip 300 may have a short side in a first direction (X direction) and a long side in a second direction (Y direction). A length of the long side of the interposer connector 400 may be equal to a length of one side of the second semiconductor chip 300. The length of the short side of the interposer connector 400 may be in a range of 1 mm to 3 mm, and a length of the long side of the interposer connector 400 may be in a range of 7 mm to 15 mm.

The lengths of the short side and the long side of the interposer connector, the height of the interposer connector, the arrangement of the conductive vias, etc. are provided as non-limiting examples. The lengths of the short and long sides of the interposer connector, the height of the interposer connector, and the arrangement of the conductive vias may be determined in consideration of the thickness, warpage, and heat dissipation characteristics of the entire package.

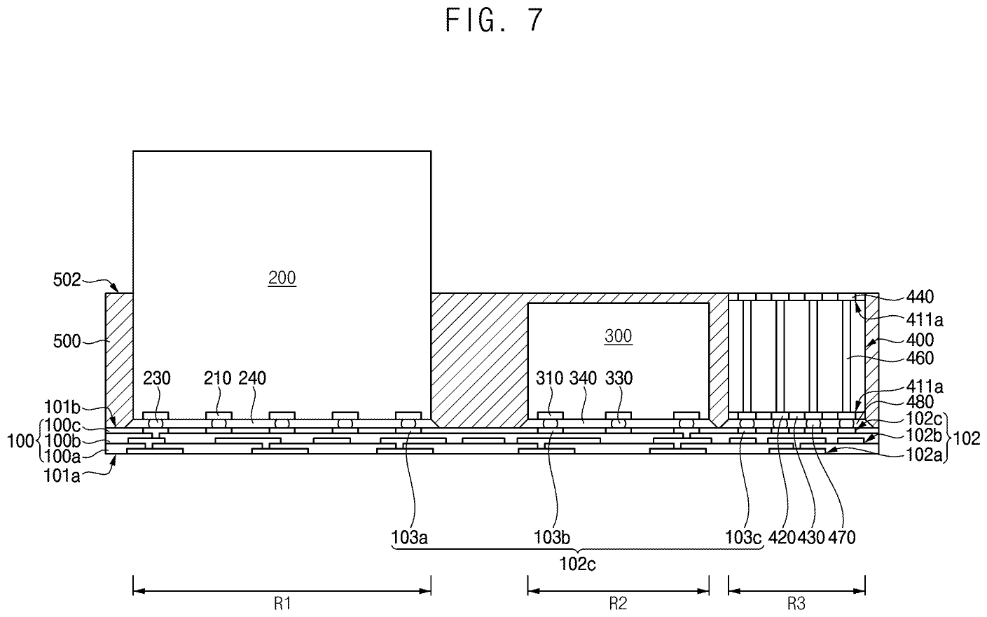

Referring to FIG. 7, a sealing member 500 may be formed on the second surface 101b of the first redistribution wiring layer 100 to cover the first semiconductor chip 200, the second semiconductor chip 300 and the interposer connector 400.

For example, the sealing member 500 may include an epoxy molding compound (EMC). The sealing member 500 may include a UV resin, polyurethane resin, silicone resin, silica filler, etc.

In example embodiments, the sealing material may be formed on the second surface 101b of the first redistribution wiring layer 100 to cover upper surfaces of the first semiconductor chip 200, the second semiconductor chip 300 and the interposer connector 400. Then, an upper portion of the sealing material may be partially removed to expose an upper portion of the first semiconductor chip 200 and the second connector pads 440 of the interposer connector 400.

Accordingly, the upper portion of the first semiconductor chip 200 and the second connector pads 440 of the interposer connector 400 may be exposed by the upper surface 502 of the sealing member 500. The upper surface of the second semiconductor chip 300 may be covered by the sealing member 500.

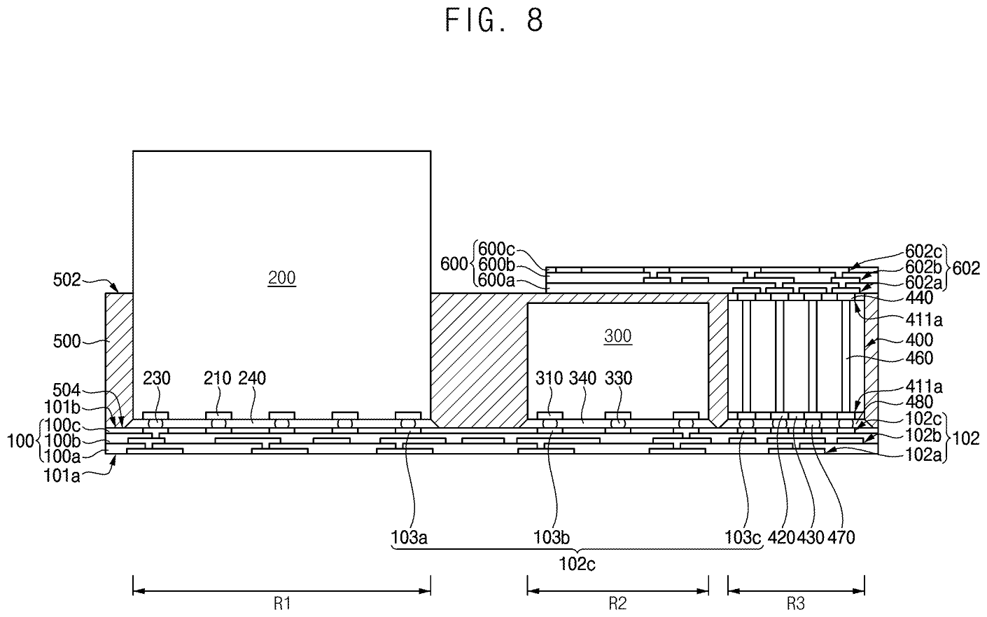

Referring to FIG. 8, a second redistribution wiring layer 600 having second redistribution wirings 602 may be formed on the upper surface 502 of the sealing member 500. The second redistribution wirings 602 may be electrically connected to the second connector pads 440. The second redistribution wiring layer 600 may be disposed on the second semiconductor chip 300 and the interposer connector 400. The second redistribution wiring layer 600 may be arranged to at least partially overlap the second semiconductor chip 300.

In example embodiments, first upper redistribution wirings 602a may be formed on at least portions of the second connector pads 440 exposed from the sealing member 500. A first upper insulating layer 600a may be formed on the sealing member 500 to cover the first upper redistribution wirings 602a.

The first upper redistribution wirings 602a may be formed, for example, by an electroplating process. After a seed layer is formed on the sealing member 500, the seed layer may be patterned and an electroplating process may be performed to form the first upper redistribution wirings. The first upper redistribution wirings may include aluminum (Al), copper (Cu), tin (Sn), nickel (Ni), gold (Au), platinum (Pt), or an alloy thereof.

The first upper insulating layer 600a may include a polymer or a dielectric layer. In particular, the first upper insulating layer 600a may be formed by a vapor deposition process, a spin coating process, etc.

Then, after the first upper insulating layer 600a is patterned to form openings that expose the first upper redistribution wirings 602a, second upper redistribution wirings 602b may be formed on the first upper insulating layer 600a to be electrically connected to the first upper redistribution wirings 602a through the openings.

For example, after a seed layer is formed on a portion of the first upper insulating layer 600a and in the opening, the seed layer may be patterned and an electroplating process may be performed to form the second upper redistribution wiring 602b. Accordingly, at least a portion of the second upper redistribution wiring 602b may directly contact the first upper redistribution wiring 602a through the opening.

Similarly, after a second upper insulating layer 600b is formed on the first upper insulating layer 600a to cover the second upper redistribution wirings 602b, the second upper insulating layer 600b may be patterned to form openings that expose the second upper redistribution wirings 602b. Then, third upper redistribution wirings 602c may be formed on the second upper insulating layer 600b to be electrically connected to the second upper redistribution wirings 602b through the openings.

After a third upper insulating layer 600c is formed on the second upper insulating layer 600b to cover the third upper redistribution wirings 602c, the third upper insulating layer 600c may be patterned to form openings that expose the third upper redistribution wirings 602c. The third upper redistribution wirings 602c exposed by the openings may be outermost redistribution wirings. A portion of the outermost redistribution wiring may include a redistribution pad portion. Although not illustrated in the figures, a bump pad such as a UBM may be formed on the redistribution pad portion.

Thus, the second redistribution wiring layer 600 having the second redistribution wiring layers 602 as a backside redistribution wiring layer (BRDL) may be formed on the sealing member 500. The second redistribution wiring layer 600 may include the first to third upper insulating layers 600a, 600b and 600c stacked on one another and the second redistribution wirings 602 in the stacked first to third upper insulating layers 600a, 600b and 600c. The second redistribution wiring 602 may include the first to third upper redistribution wirings 602a, 602b and 602c. The second redistribution wiring layer 600 may have a first surface 601a and a second surface 601b opposite to the first surface 601a.

The numbers, sizes, arrangements, etc. of the upper insulating layers and the upper redistribution wirings of the second redistribution wiring layer are provided as non-limiting examples.

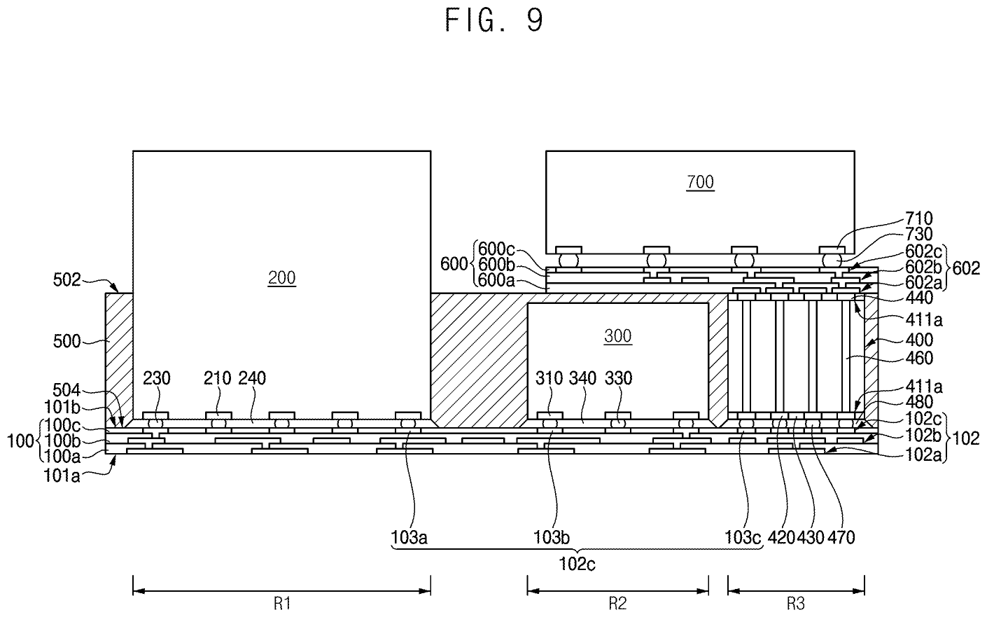

Referring to FIG. 9, a third semiconductor chip 700 as an upper package may be stacked on the second redistribution wiring layer 600 of a lower package of FIG. 8.

In example embodiments, the third semiconductor chip 700 may be mounted on the second surface 201b of the second redistribution wiring layer 600 by a flip chip bonding method. The third semiconductor chip 700 may be arranged such that a front surface on which third chip pads 710 are formed, that is, an active surface, faces the second redistribution wiring layer 600. The third chip pads 710 of the third semiconductor chip 700 may be electrically connected to the second redistribution wirings 602 of the second redistribution wiring layer 600 by third conductive bumps 730.

Although one third semiconductor chip is illustrated as being mounted on the second redistribution wiring layer 600, in some implementations, the upper package may include a package substrate and at least one third semiconductor chip mounted on the package substrate. The package substrate of the upper package may be mounted on the second redistribution wiring layer via the third conductive bumps.

External connection members 800 (see FIG. 1) may be formed on the first surface 101a of the first redistribution wiring layer 100. The external connection members such as solder balls or solder bumps may be respectively formed on bonding pads on the redistribution pad portions of the first lower redistribution wirings 102a of the first redistribution wiring layer 100.

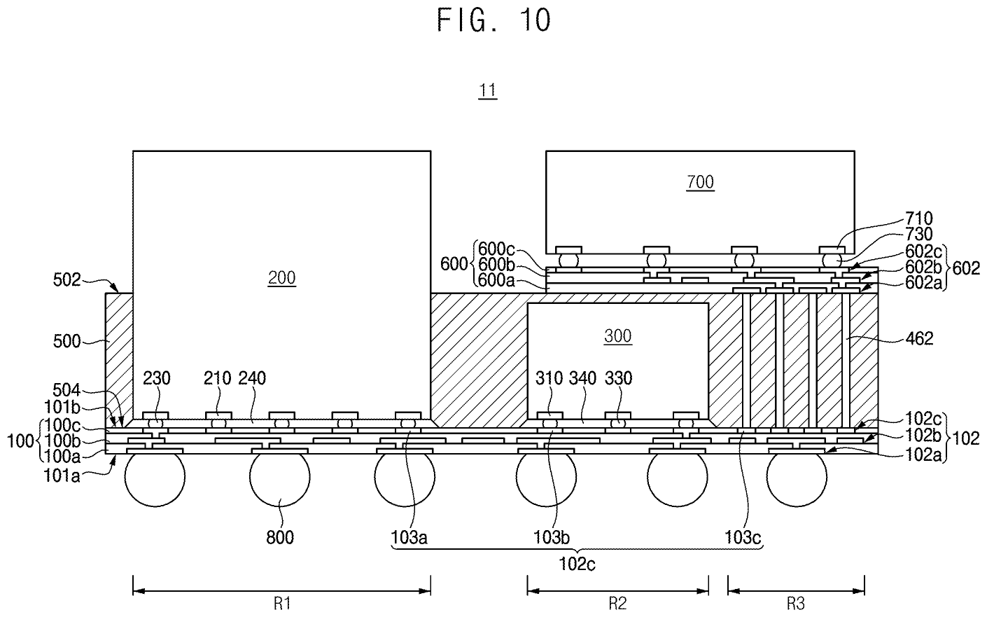

FIG. 10 is a cross-sectional view illustrating a semiconductor package in accordance with example embodiments. The semiconductor package may be substantially the same as the semiconductor package described with reference to FIGS. 1 to 3 except for arrangements of conductive vias. Thus, same reference numerals may be used to refer to the same or like elements and any further explanation concerning the above elements will not be repeated.

Referring to FIG. 10, a semiconductor package 11 may include a first redistribution wiring layer 100, a first semiconductor chip 200, a second semiconductor chip 300, a plurality of conductive vias 462, a sealing member 500 and a second redistribution wiring layer 600. In addition, the semiconductor package 11 may further include a third semiconductor chip 700 and external connection members 800.

In example embodiments, the plurality of conductive vias 462 may be provided in a connector region R3 on a second surface 101b of the first redistribution wiring layer 100. The conductive vias 462 may be provided to extend through the sealing member 500.

The conductive via 462 may extend upward on a third uppermost redistribution wiring 103c of the first redistribution wiring layer 100. A first end portion of the conductive via 462 may be electrically connected to the third uppermost redistribution wiring 103c of the first redistribution wiring layer 100. A second end portion of the conductive via 462 that is opposite to the first end portion may be electrically connected to a second redistribution wiring 602 of the second redistribution wiring layer 600.

Thus, the first semiconductor chip 200 and the second semiconductor chip 300 may be electrically connected to the third semiconductor chip 700 by first redistribution wirings 102, the conductive vias 462 and the second redistribution wirings 602.

Hereinafter, a method of manufacturing the semiconductor package of FIG. 10 will be explained.

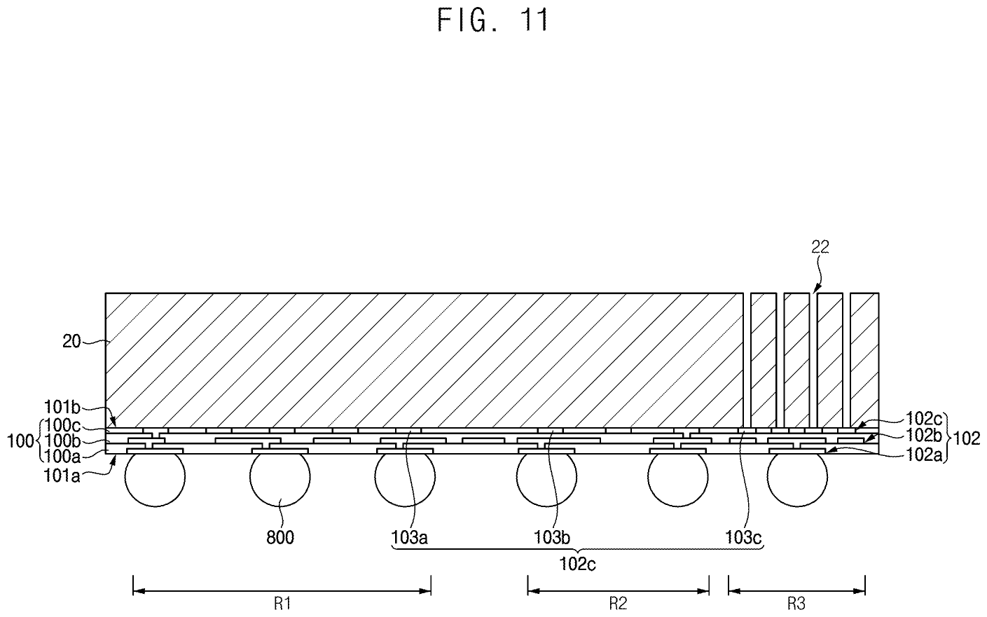

FIGS. 11 to 15 are cross-sectional views illustrating a method of manufacturing a semiconductor package in accordance with example embodiments.

Referring to FIGS. 11 to 13, first, processes that are the same as or similar to the processes described with reference to FIG. 4 may be performed to form a first redistribution wiring layer 100 having first redistribution wirings 102. A plurality of conductive vias 462 may be formed on a connector region R3 on a second surface 101b of the first redistribution wiring layer 100.

As illustrated in FIG. 11, a photoresist layer may be formed on the second surface 101b of the first redistribution wiring layer 100. An exposure process may be performed on the photoresist layer to form a photoresist pattern 20 having openings 22 for forming the plurality of conductive vias on the second surface 101b of the third region R3 of the first redistribution wiring layer 100. The opening 22 may expose at least a portion of a third uppermost redistribution wiring 103c in the third region R3.

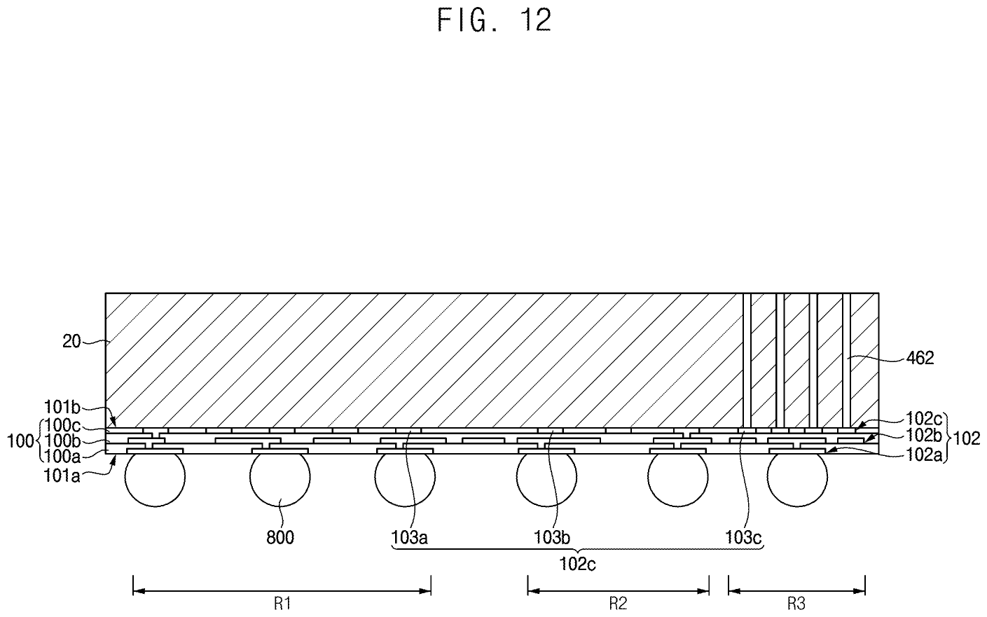

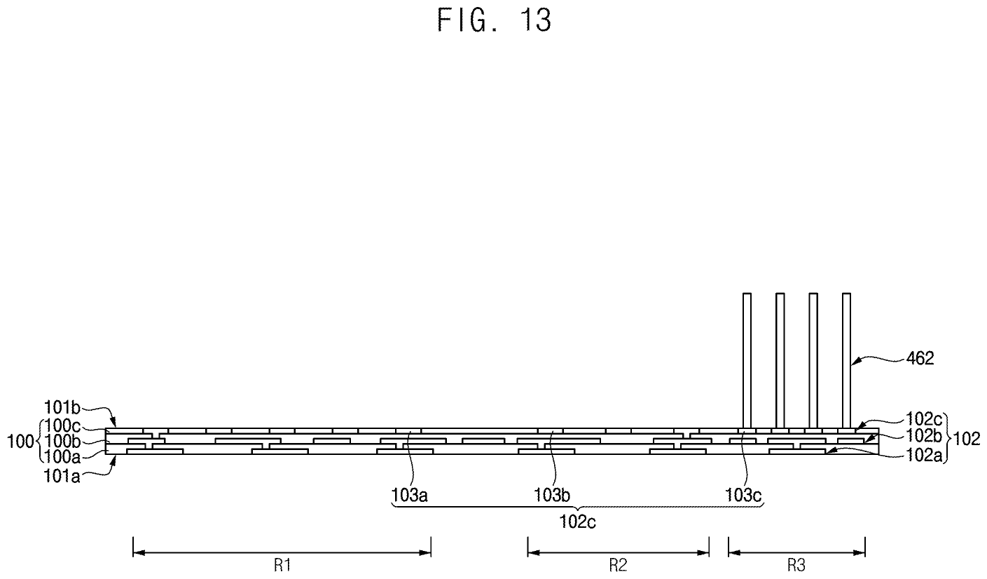

Then, as illustrated in FIGS. 12 and 13, an electroplating process may be performed to fill up the openings 22 of the photoresist pattern 20 with a conductive material to form the conductive vias 462. Then, the photoresist pattern 20 may be removed by a strip process.

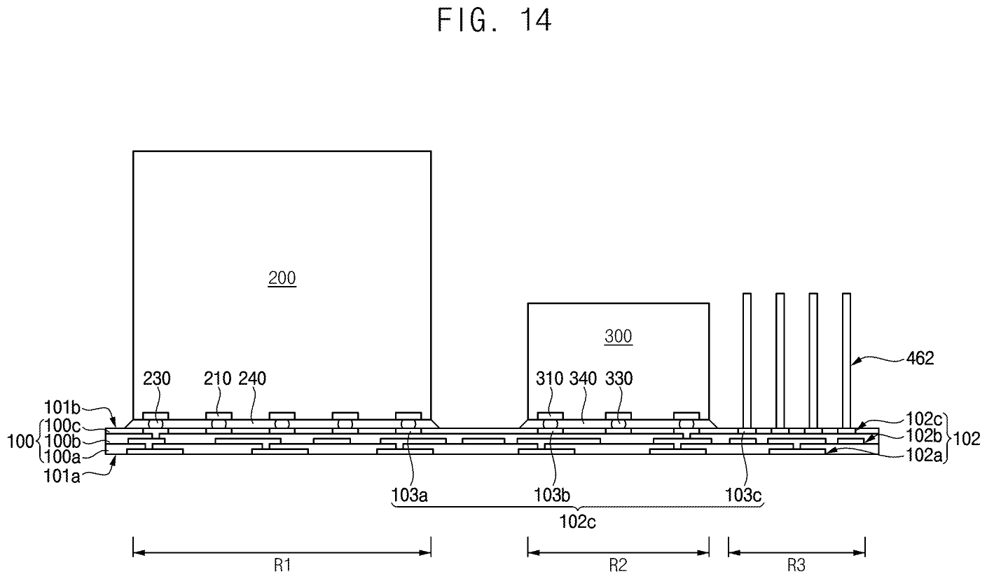

Referring to FIG. 14, processes the same as or similar to the processes described with reference to FIGS. 5 and 6 may be performed to mount a semiconductor chip 200 on a first region R1 and to mount a second semiconductor chip 300 on a second region R2 on the second surface 101b of the first redistribution wiring layer 100.

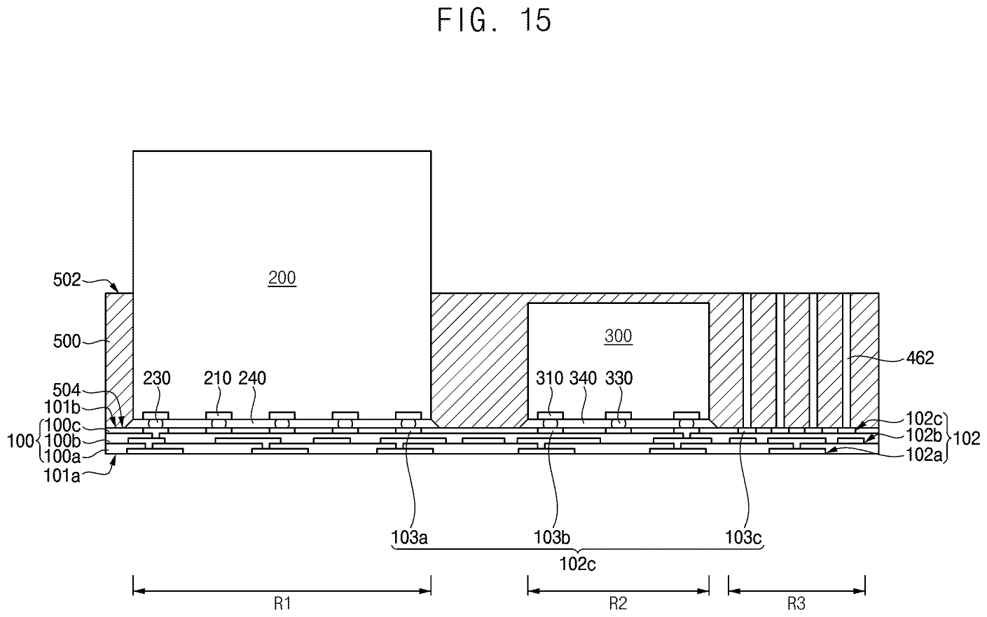

Referring to FIG. 15, a sealing member 500 may be formed on the second surface 101b of the first redistribution wiring layer 100 to cover the first semiconductor chip 200, the second semiconductor chip 300 and the plurality of conductive vias 462.

After a sealing material is formed on the second surface 101b of the first redistribution wiring layer 100 to cover upper surfaces of the first semiconductor chip 200, the second semiconductor chip 300 and the plurality of conductive vias 462, an upper portion of the sealing material may be partially removed to expose an upper portion of the first semiconductor chip 200 and end portions of the conductive vias 462.

Then, processes the same as, or similar to, the processes described with reference to FIGS. 8 and 9 may be performed to form a second redistribution wiring layer 600 having second redistribution wirings 602 on an upper surface 502 of the sealing member 500. A third semiconductor chip 700 as an upper package may be stacked on the second redistribution wiring layer 600.

The second redistribution wirings 602 may be electrically connected to the conductive vias 40. The second redistribution wiring layer 600 may be arranged on the second semiconductor chip 300 and the conductive vias 462. The second redistribution wiring layer 600 may be arranged to at least partially overlap the second semiconductor chip 300.

Then, external connection members 800 (see to FIG. 10) may be formed on a first surface 101a of the first redistribution wiring layer 100 to complete the semiconductor package 11 of FIG. 10.

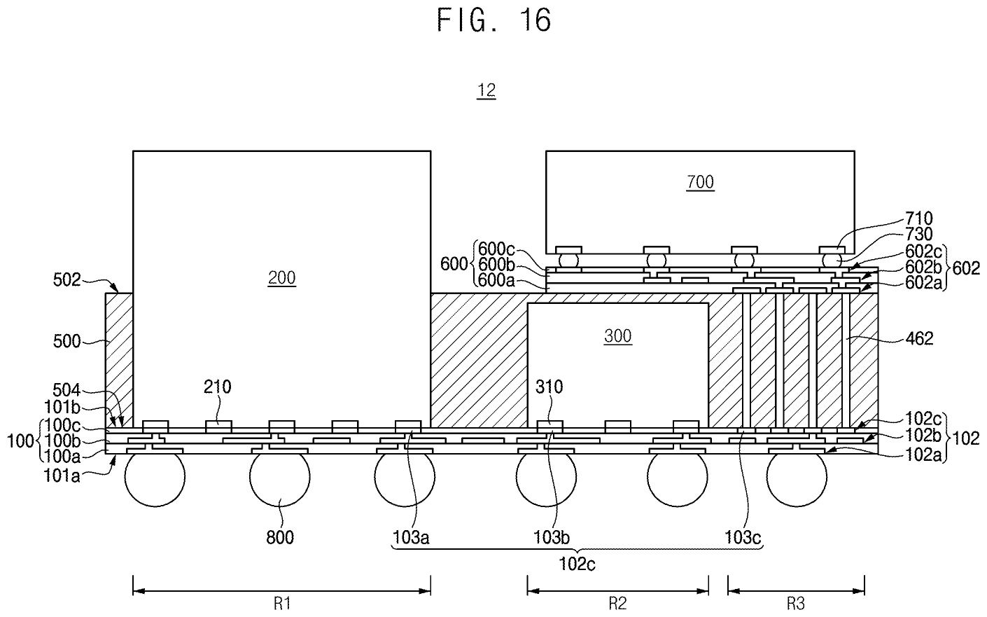

FIG. 16 is a cross-sectional view illustrating a semiconductor package in accordance with example embodiments. The semiconductor package may be substantially the same as the semiconductor package described with reference to FIG. 10, except for a mounting structure of the first and second semiconductor chips. Thus, same reference numerals may be used to refer to the same or like elements and any further repetitive explanation concerning the above elements will not be repeated.

Referring to FIG. 16, a semiconductor package 12 may include a first redistribution wiring layer 100, a first semiconductor chip 200, a second semiconductor chip 300, a plurality of conductive vias 462, a sealing member 500 and a second redistribution wiring layer 600. In addition, the semiconductor package 11 may further include a third semiconductor chip 700 and external connection members 800.

In example embodiments, a front surface of the first semiconductor chip 200 may contact a second surface 101b of the first redistribution wiring layer 100. First chip pads 210 of the first semiconductor chip 200 may be exposed from a lower surface 504 of the sealing member 500. The first chip pads 210 of the first semiconductor chip 200 may be bonded to third lower redistribution wirings 102c of the first redistribution wiring layer 100.

The front surface of the second semiconductor chip 300 may contact the second surface 101b of the first redistribution wiring layer 100. Second chip pads 310 of the second semiconductor chip 300 may be exposed from the lower surface 504 of the sealing member 500. The second chip pads 310 of the second semiconductor chip 300 may be bonded to the third lower redistribution wirings 102c of the first redistribution wiring layer 100.

Hereinafter, a method of manufacturing the semiconductor package of FIG. 16 will be explained.

First, after first and second semiconductor chips are disposed on a second carrier substrate, a sealing member may be formed on the second carrier substrate to cover the first and second semiconductor chips.

In example embodiments, the first semiconductor chip may be arranged on the second carrier substrate such that a second surface opposite to the first surface on which first chip pads are formed faces the second carrier substrate. Similarly, the second semiconductor chip may be arranged on the second carrier substrate such that a second surface opposite to a first surface on which second chip pads are formed faces the second carrier substrate.

The sealing member may expose front surfaces of the first and second semiconductor chips and cover only side surfaces of the first and second semiconductor chips.

Then, a first redistribution wiring layer having first redistribution wirings may be formed on the sealing member.

Among the first redistribution wirings, third lower redistribution wirings may be formed on the first chip pads of the first semiconductor chip and the second chip pads of the second semiconductor chip. Thus, the first and second semiconductor chips may be electrically connected to the first redistribution wirings.

Then, a plurality of conductive vias may be formed in the sealing member and a second redistribution wiring layer may be formed on the sealing member.

It will be appreciated that the method of manufacturing the semiconductor package is not limited thereto and may be performed in various modified ways.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

By way of summation and review, example embodiments provide a semiconductor package capable of increasing the degree of freedom of IP arrangement and improved heat dissipation characteristics and provide a method of manufacturing the semiconductor package.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the embodiments as set forth in the following claims.

What is claimed is:

1. A semiconductor package, comprising:
a first redistribution wiring layer having first redistribution wirings;
a first semiconductor chip disposed on the first redistribution wiring layer, the first semiconductor chip being arranged such that a front surface on which first chip pads are formed faces the first redistribution wiring layer, and has a first thickness from the first redistribution wiring layer;
a second semiconductor chip disposed on the first redistribution wiring layer, the second semiconductor chip being spaced apart from the first semiconductor chip and arranged such that a front surface on which second chip pads are formed faces the first redistribution wiring layer, and having a second thickness from the first redistribution wiring layer and smaller than the first thickness;
a sealing member covering the first semiconductor chip and the second semiconductor chip on the first redistribution wiring layer;
a plurality of conductive vias provided in the sealing member and electrically connected to the first redistribution wirings;
a second redistribution wiring layer disposed on the sealing member and having second redistribution wirings electrically connected to the plurality of conductive vias; and
at least one third semiconductor chip disposed on the second redistribution wiring layer and electrically connected to the second redistribution wirings.

2. The semiconductor package as claimed in claim 1, wherein the sealing member exposes an upper portion of the first semiconductor chip.

3. The semiconductor package as claimed in claim 1, wherein the first thickness is in a range of 0.5 mm to 1.0 mm, and the second thickness is in a range of 0.1 mm to 0.5 mm.

4. The semiconductor package as claimed in claim 1, wherein the second redistribution wiring layer overlaps the second semiconductor chip.

5. The semiconductor package to claim 1, further comprising:
at least one interposer connector disposed on the first redistribution wiring layer and adjacent to the second semiconductor chip,
the at least one interposer connector comprises:
a connector substrate having a first surface facing the first redistribution wiring layer and a second surface opposite to the first surface;
the plurality of conductive vias penetrating the connector substrate; and
conductive bumps provided on the first surface and electrically connected to the plurality of conductive vias,
wherein the conductive bumps are electrically connected to the first redistribution wirings.

6. The semiconductor package as claimed in claim 5, wherein the at least one interposer connector further comprises:
first connector pads respectively disposed on end portions of the plurality of conductive vias on the first surface of the connector substrate and to which the conductive bumps are bonded; and
second connector pads respectively disposed on other end portions of the plurality of conductive vias on the second surface of the connector substrate.

7. The semiconductor package as claimed in claim 6, wherein the second connector pads are electrically connected to the second redistribution wirings.

8. The semiconductor package as claimed in claim 6, wherein the connector substrate includes a silicon material.

9. The semiconductor package as claimed in claim 1, wherein the first semiconductor chip is mounted on the first redistribution wiring layer via conductive bumps that are disposed on the first chip pads, and the second semiconductor chip is mounted on the first redistribution wiring layer via conductive bumps that are disposed on the second chip pads.

10. The semiconductor package as claimed in claim 1, wherein the first and second semiconductor chips include a logic chip, and the at least one third semiconductor chip includes a memory chip.

11. A semiconductor package, comprising:
a first redistribution wiring layer including a first chip mounting region, a second chip mounting region and a connector region spaced apart from each other, the first redistribution wiring layer having first redistribution wirings;
a first semiconductor chip mounted on the first chip mounting region on the first redistribution wiring layer;
a second semiconductor chip mounted on the second chip mounting region on the first redistribution wiring layer;
at least one interposer connector disposed on the connector region on the first redistribution wiring layer, the at least one interposer connector including a connector substrate having a plurality of conductive vias penetrating therethrough, first and second connector pads respectively provided at both end portions of the plurality of conductive vias, and conductive bumps respectively formed on the first connector pads, the at least one interposer connector being mounted on the first redistribution wiring layer via the conductive bumps;
a sealing member on the first redistribution wiring layer and covering the first semiconductor chip, the second semiconductor chip and the at least one interposer connector;
a second redistribution wiring layer disposed on the sealing member and having second redistribution wirings electrically connected to the second connector pads; and
a third semiconductor chip disposed on the second redistribution wiring layer, the third semiconductor chip being spaced apart from one side surface of the first semiconductor chip, and electrically connected to the second redistribution wirings,
wherein the first semiconductor chip has a first thickness, and the second semiconductor chip has a second thickness less than the first thickness.

12. The semiconductor package as claimed in claim 11, wherein the sealing member exposes an upper portion of the first semiconductor chip.

13. The semiconductor package as claimed in claim 11, wherein the first thickness is in a range of 0.5 mm to 1.0 mm, and the second thickness is in a range of 0.1 mm to 0.5 mm.

14. The semiconductor package as claimed in claim 11, wherein the second redistribution wiring layer overlaps the second semiconductor chip.

15. The semiconductor package as claimed in claim 11, wherein the connector substrate includes a silicon material.

16. The semiconductor package as claimed in claim 11, wherein:
the first semiconductor chip is mounted on the first redistribution wiring layer via conductive bumps that are disposed on first chip pads of the first semiconductor chip, and
the second semiconductor chip is mounted on first redistribution wiring layer via conductive bumps that are disposed on second chip pads of the second semiconductor chip.

17. The semiconductor package as claimed in claim 11, wherein:
the first and second semiconductor chips include a logic chip, and
the third semiconductor chip includes a memory chip.

18. The semiconductor package as claimed in claim 11, wherein, when viewed from a plan view, the connector substrate has a rectangular shape having a short side in a first direction and a long side in a second direction orthogonal to the first direction.

19. The semiconductor package as claimed in claim 11, further comprising:
external connection members disposed on an outer surface of the first redistribution wiring layer and electrically connected to the first redistribution wirings.

20. A semiconductor package, comprising:
a first redistribution wiring layer including a first chip mounting region, a second chip mounting region, and a connector region, the first chip mounting region, second chip mounting region, and connector region being spaced apart from each other, and the first redistribution wiring layer having first redistribution wirings;
a first semiconductor chip mounted on the first chip mounting region on the first redistribution wiring layer;
a second semiconductor chip mounted on the second chip mounting region on the first redistribution wiring layer;
a sealing member on the first redistribution wiring layer, the sealing member covering the first semiconductor chip and the second semiconductor chip;
a plurality of conductive vias disposed on the connector region on the first redistribution wiring layer, the conductive vias penetrating the sealing member to be electrically connected to the first redistribution wirings;
a second redistribution wiring layer disposed on the sealing member and having second redistribution wirings electrically connected to the plurality of conductive vias; and
a third semiconductor chip disposed on the second redistribution wiring layer, the third semiconductor chip being spaced apart from one side of the first semiconductor chip and electrically connected to the second redistribution wirings,
wherein the first semiconductor chip has a first thickness, and the second semiconductor chip has a second thickness less than the first thickness.
